(19) United States
(12) Patent Application Publication
(10) Pub. No.: US 2025/0294688 A1
(43) Pub. Date: Sep. 18, 2025

(54) ELECTRONIC DEVICE TEMPERATURE REGULATING APPARATUS

(71) Applicant: Bruce Hunt, North Canton, OH (US)

(72) Inventor: Bruce Hunt, North Canton, OH (US)

(21) Appl. No.: 19/069,474

(22) Filed: Mar. 4, 2025

Related U.S. Application Data
(60) Provisional application No. 63/564,539, filed on Mar. 13, 2024.

(51) Int. Cl. H05K 5/02; H05K 7/20

(52) U.S. Cl. CPC H05K 5/02; H05K 7/20

(57) ABSTRACT

The present disclosure, in some embodiments, relates to an electronic device temperature regulating apparatus. The electronic device temperature regulating apparatus includes a first compartment arranged between a first membrane including a first material having a first insulative value and an intervening membrane opposing the first membrane. A second compartment is arranged between the intervening membrane and a second membrane including a second material having a second insulative value. The intervening membrane includes a thermal transmission region that is directly between the first compartment and the second compartment. The thermal transmission region has a third insulative value that is less than the first insulative value and the second insulative value.

### REFERENCE TO RELATED APPLICATION

This application claims the benefit of U.S. Provisional Application No. 63/564,539, filed on Mar. 13, 2024, the contents of which are incorporated by reference in their entirety.

### BACKGROUND

Electronic devices, such as cell phones, tablet computers, and/or the like are susceptible to overheating at high temperatures. When electronic devices overheat, they can experience degradation of performance, malfunctioning, and/or even completely shut down.

### BRIEF DESCRIPTION OF THE DRAWINGS

Aspects of the present disclosure are best understood from the following detailed description when read with the accompanying figures. It is noted that, in accordance with the standard practice in the industry, various features are not necessarily drawn to scale. In fact, the dimensions of the various features may be arbitrarily increased or reduced for clarity of discussion.

FIG. 1 illustrates some embodiments of a block diagram of an electronic device temperature regulating apparatus configured to maintain a temperature of an electronic device within a safe operating range.

FIGS. 2A-2B illustrate some additional embodiments of a disclosed electronic device temperature regulating apparatus.

FIGS. 3A-3B illustrate some additional embodiments of a disclosed electronic device temperature regulating apparatus.

FIGS. 4A-4C illustrate some additional embodiments of a disclosed electronic device temperature regulating apparatus.

FIGS. 5A-5B illustrate plan-views of some alternative embodiments of disclosed electronic device temperature regulating apparatuses.

FIG. 6 illustrates some additional embodiments of a disclosed electronic device temperature regulating apparatus.

FIGS. 7A-7B illustrate some embodiments of first and second compartments of a disclosed electronic device temperature regulating apparatus.

FIG. 8 illustrates a flow diagram of some embodiments of a method of forming a disclosed electronic device temperature regulating apparatus.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Modern-day electronic devices are built to operate within a regular range of operating temperatures (e.g., between approximately 32° Fahrenheit and approximately 95° Fahrenheit). Exposing electronic devices to temperatures that are outside of the regular range of operating temperatures can negatively affect operation of the electronic devices. For example, cellular phones (e.g., smartphones) comprise powerful processors that are run by high-capacity batteries. The combination of powerful processors and high-capacity batteries make cell phones susceptible to overheating, especially in the summer when high temperatures are common. Prolonged exposure to high temperatures can slow down a phone, damage internal hardware components of a phone, overheat a battery leading to battery leakage, damage a circuit board, and/or the like. Similarly, cellular phones will typically turn off when exposed to temperatures below around 32° Fahrenheit, as extreme cold can significantly impact a battery's ability to function properly, causing it to drain quickly and eventually shut down a cellular phone.

Cell phone manufacturers generally recommend to avoid using a cell phone when it is at a temperature of greater than approximately 95° Fahrenheit (F), and to avoid storing a cell phone at a temperature higher than 113° F. To help users avoid damaging their phone, many phones will post a warning on a screen if the phone gets too hot. The phones may also shut down certain features and/or entirely in order to help cool down. There are steps that a user can take to cool down an overheating cell phone and prevent damage. For example, a user can avoid keeping a phone in a car or a dark colored bag. However, such steps are limited in their effectiveness and ultimately may be ineffective at keeping a temperature of a cell phone within recommended operating ranges.

The present disclosure relates to an electronic device temperature regulating apparatus that is configured to maintain a temperature of an electronic device (e.g., a smartphone) within a safe operating range that is above or below a temperature of a surrounding ambient environment. In some embodiments, the electronic device temperature regulating apparatus may comprise a first compartment and a second compartment that is separated from the first compartment by an intervening surface comprising a thermal transmission region. The thermal transmission region provides for thermal communication between the first compartment and the second compartment. During operation, the first compartment is configured to hold an electronic device (e.g., a cell phone) and the second compartment is configured to hold a temperature regulation element. The thermal transmission surface is configured to allow for the transfer of heat between the first compartment and the second compartment. By allowing for heat to be transferred between the first and second compartments, the temperature regulation element can hold the electronic device within a temperature range that allows for proper operation and/or that avoids damage.

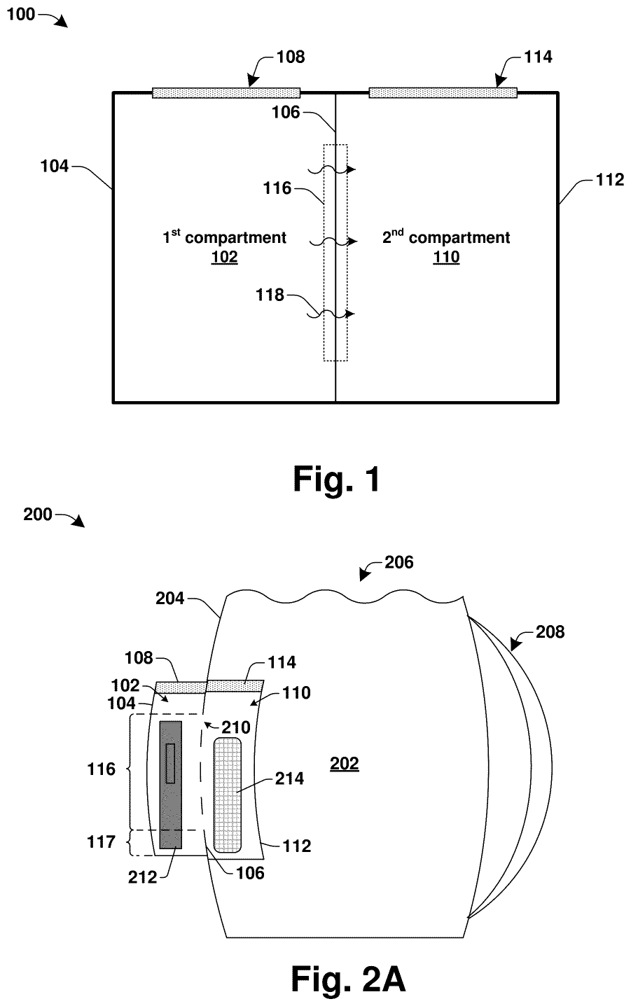

FIG. 1 illustrates some embodiments of a block diagram of an electronic device temperature regulating apparatus 100 configured to maintain a temperature of an electronic device within a safe operating range.

The electronic device temperature regulating apparatus 100 comprises a first compartment 102 and a second compartment 110 neighboring the first compartment 102. The first compartment 102 is separated from the second compartment 110 by an intervening membrane 106. The first compartment 102 may be configured to receive an electronic device (e.g., a cellular phone, a smart phone, a tablet computer, etc.) and the second compartment 110 may be configured to receive a temperature regulation element (e.g., a cooling element, a heating element, etc.).

The first compartment 102 is formed by and arranged between the intervening membrane 106 and an opposing first membrane 104. The first membrane 104 includes a first material having a first insulative value. In some embodiments, the first insulative value is a first R-value. In some embodiments, a first opening 108 may be configured to selectively provide access to the first compartment 102.

The second compartment 110 is formed by and arranged between the intervening membrane 106 and an opposing second membrane 112. The second membrane 112 includes a second material having a second insulative value. In some embodiments, the second insulative value is a second R-value. In some embodiments, a second opening 114 may be configured to selectively provide access to the second compartment 110.

The intervening membrane 106 includes a thermal transmission region 116 (e.g., a thermal transmission partition) that is arranged directly between the first compartment 102 and the second compartment 110. In some embodiments, the thermal transmission region 116 of the intervening membrane 106 has a third insulative value. The third insulative value is less than the first insulative value and the second insulative value. In some embodiments, the third insulative value is a third R-value that is less than the first R-value and the second R-value.

Because the thermal transmission region 116 has a lower insulative value than the first membrane 104 and the second membrane 112, the thermal transmission region 116 is configured to allow for thermal energy 118 (e.g., heat) to efficiently transfer between the first compartment 102 and the second compartment 110. By allowing thermal energy to efficiently transfer between the first compartment 102 and the second compartment 110, a temperature regulation element disposed within the second compartment 110 can be used to maintain a temperature of an electronic device within the first compartment 102 at a safe operating range (e.g., between approximately 32° Fahrenheit and approximately 95° Fahrenheit). By utilizing the temperature regulation element to maintain a temperature of an electronic device within the first compartment 102 to be within a safe operating range overheating of an electronic device can be avoided, thereby avoiding performance degradation of the electronic device, damage of the electronic device, and/or the like.

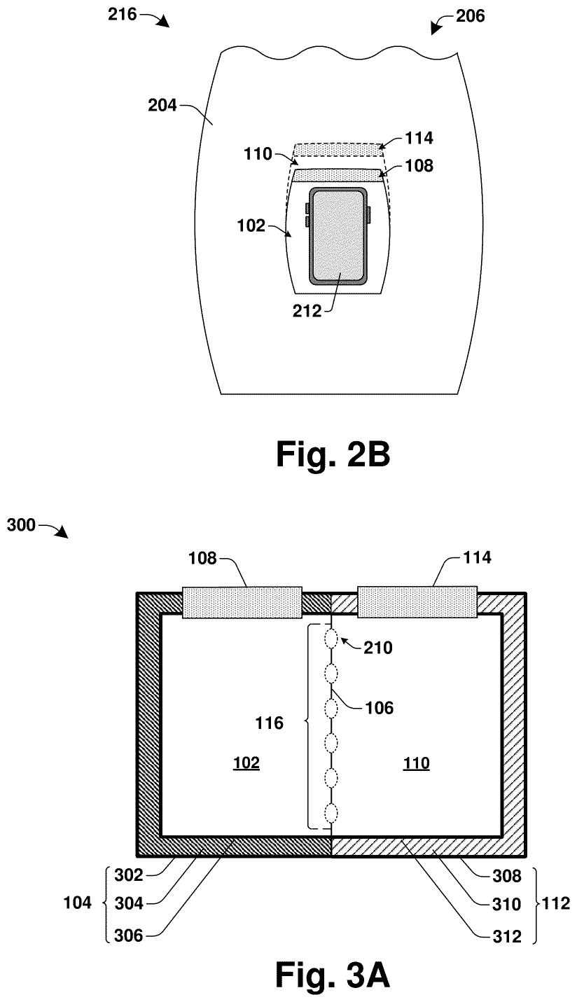

FIG. 2A illustrates a cross-sectional view of some additional embodiments of a disclosed electronic device temperature regulating apparatus 200.

The electronic device temperature regulating apparatus 200 comprises a bag having a flexible housing 204 (e.g., casing) that encloses an interior cavity 202. The bag has an exterior opening 206 that can be selectively opened and closed to provide access to the interior cavity 202. In some embodiments, the flexible housing 204 has an exterior surface (e.g., an outer surface) that is white, so as to reduce the bag's absorption of thermal energy from the sun. In other embodiments, the flexible housing 204 may have an exterior surface that is silver, cream, yellow, purple, green, gray, and/or other similar colors. In some embodiments, one or more shoulder straps 208 may be coupled to the flexible housing 204 of the bag.

A first membrane 104 (e.g., a first flexible membrane) is attached to a first side (e.g., an exterior surface) of the flexible housing 204 to form a first compartment 102. The first compartment 102 has a first opening 108. In some embodiments, the first opening 108 can be selectively closed and opened to provide access to the first compartment 102. A second membrane 112 (e.g., a second flexible membrane) is attached to a second side (e.g., an interior surface) of the flexible housing 204 to form a second compartment 110 within the interior cavity 202. The second compartment 110 has a second opening 114. In some embodiments, the second opening 114 can be selectively closed and opened to provide access to the second compartment 110. In some embodiments, the interior cavity 202 has a first size, the first compartment 102 has a second size that is smaller than the first size, and the second compartment 110 has a third size that is smaller than the first size. In some embodiments, the second size may be substantially equal to the third size. In other embodiments, the second size may be different than the third size.

It has been appreciated that exposing an electronic device to direct sunlight can crack or pixelate a display screen and/or cause it to become unresponsive. Therefore, in some embodiments the first membrane 104 may be opaque, so as to mitigate (e.g., prevent) sunlight from hitting an electronic device. In other embodiments, the first membrane 104 may comprise a coated plastic that is configured to reflect light while maintaining a transparent appearance (e.g., using a dielectric mirror), thereby enabling an electronic device's screen to be seen in the first compartment 102 while still protecting the electronic device from exposure to direct sunlight.

In some embodiments, the bag may comprise one or more fastening members (not shown), which are configured to selectively close the first opening 108, the second opening 114, and/or the exterior opening 206. In some embodiments, the one or more fastening members may comprise hook and loop fasteners (e.g., hook and loop straps). In other embodiments, the one or more fastening members may comprise a zipper, buttons, and/or the like. In some embodiments, the one or more fastening members may form a water-tight seal. In some such embodiment, the flexible housing 204 of the bag and the first membrane 104 may comprise waterproof materials, so as to enable the interior cavity 202 and the first compartment 102 to remain dry if the bag is submerged in a liquid (e.g., water).

The bag comprises an intervening membrane 106 disposed between the first compartment 102 and the second compartment 110. The intervening membrane 106 includes a thermal transmission region 116 arranged directly between the first compartment 102 and the second compartment 110. The thermal transmission region 116 provides for thermal communication between the first compartment 102 and the second compartment 110. In some embodiments, the intervening membrane 106 may comprise a same material as the flexible housing 204 of the bag. In some such embodiments, the intervening membrane 106 may be a part of the flexible housing 204 of the bag. In other embodiments, the intervening membrane 106 may be a different material than the flexible housing 204 of the bag. In some embodiments, the intervening membrane 106 may comprise or be a moisture wicking fabric. The moisture wicking fabric may be configured to move moisture away from an electronic device to avoid exposing the electronic device to moisture. In some embodiments, the intervening membrane 106 may comprise or be a waterproof material configured to mitigate and/or prevent transmission of moisture between the first compartment 102 and the second compartment 110.

In some embodiments, the first membrane 104 may have a first thermal transfer coefficient (e.g., heat transfer coefficient), the second membrane 112 may have a second thermal transfer coefficient, and the intervening membrane 106 may have a third thermal transfer coefficient within the thermal transmission region 116. The third thermal transfer coefficient is larger than the first thermal transfer coefficient and the second thermal transfer coefficient. In some embodiments, the intervening membrane 106 comprises a material having a fourth thermal transfer coefficient that is smaller than the third thermal transfer coefficient. In such embodiments, the intervening membrane 106 may comprise a plurality of perforations 210 extending through the material within the thermal transmission region 116. The plurality of perforations 210 increase thermal transmission within the thermal transmission region 116, so as to give thermal transmission region 116 the third thermal transfer coefficient.

In some embodiments, the plurality of perforations 210 are configured to have a cumulative area that is a fraction of an area of the intervening membrane 106. For example, the plurality of perforations 210 may have a cumulative area that is less than approximately 75% of the area of the intervening membrane 106, that is less than approximately 50% of the area of the intervening membrane 106, that is less than approximately 40% of the area of the intervening membrane 106, or other similar values. By having a cumulative area of the plurality of perforations 210 be a fraction of the area of the intervening membrane 106, a transfer of heat energy between the first compartment 102 and the second compartment 110 can be controlled, so as to regulate a temperature within the first compartment 102. For example, a smaller cumulative area of the plurality of perforations 210 may result in less transfer of heat energy and a higher temperature within the first compartment 102.

In some embodiments, the thermal transmission region 116 may extend between outermost edges (e.g., between a top and a bottom) of the first compartment 102 and/or the second compartment 110. In other embodiments, the thermal transmission region 116 may be set back from one or more outermost edges of the first compartment 102 and/or the second compartment 110. In such embodiments, the intervening membrane 106 may comprise a peripheral region 117 arranged along one or more edges of the thermal transmission region 116 (e.g., along a top, a bottom, and/or one or more sides of the thermal transmission region 116). The peripheral region 117 may have an insulative value that is greater than the thermal transmission region 116. In some embodiments, the peripheral region 117 may have an insulative value that is substantially equal to the first membrane 104, the second membrane 112, and/or the flexible housing 204.

In some embodiments, the thermal transmission region 116 and the peripheral region 117 may comprise and/or be different materials that are attached to one another. In some other embodiments, the thermal transmission region 116 and the peripheral region 117 may comprise and/or be a same material but have characteristics that give different thermal insulative values to the thermal transmission region 116 and the peripheral region 117. For example, the thermal transmission region 116 and the peripheral region 117 may have different thicknesses, different porosities (e.g., the thermal transmission region 116 may have one or more holes extending through a material of the thermal transmission region 116 while the peripheral region 117 may be devoid of holes), and/or the like.

During operation, the first compartment 102 may be configured to receive an electronic device 212 and the second compartment 110 may be configured to receive a temperature regulation element 214. In some embodiments, the electronic device 212 may comprise or be a cellular phone, a tablet computer, a handheld gaming console, etc. In some embodiments, the temperature regulation element 214 may comprise a cooling element, such as a reuseable ice pack, ice, or the like. In some embodiments, the cooling element is configured to cool the second compartment 110 to a lower temperature than the interior cavity 202. In other embodiments, the temperature regulation element 214 may comprise a heating element, such as a resistive heater, a chemical mixture (e.g., including iron powder, water, salt, activated charcoal and wood fiber), or the like.

Having the thermal transmission region 116 with a larger thermal transfer coefficient than the second membrane 112, will allow more heat to pass through the intervening membrane 106 than the second membrane 112, thereby allowing for the temperature regulation element 214 to affect a temperature of the first compartment 102 to a greater extent than the interior cavity 202 (e.g., to allow a cooling element to cool the first compartment 102 to a greater extent than the interior cavity 202). Having the thermal transmission region 116 with a larger thermal transfer coefficient than the second membrane 112 may also allow for the temperature regulation element 214 to maintain a desired temperature for a longer period of time, since thermal energy is conserved by the second membrane 112.

FIG. 2B illustrates a plan-view 216 of some embodiments of the disclosed electronic device temperature regulating apparatus 200 of FIG. 2A.

As can be seen in plan-view 216, the first compartment 102 is arranged along a part of the flexible housing 204 of the bag. In some embodiments, the first compartment 102 may be set back from outer edges of the flexible housing 204. The second compartment 110 overlaps the first compartment along a vertical and lateral direction. In some embodiments, the first compartment 102 and the second compartment 110 largely overlap one another. For example, more than 80% of areas of the first compartment 102 and the second compartment 110 may overlap.

In some embodiments, the first membrane, the second membrane, and the intervening membrane may comprise single layer membranes (e.g., membranes that are a same material extending between opposing sides of the membranes). In other embodiments, one or more of the first membrane, the second membrane, and the intervening membrane may comprise multi-layered membranes (e.g., membranes that comprise different materials between opposing sides of the membranes).

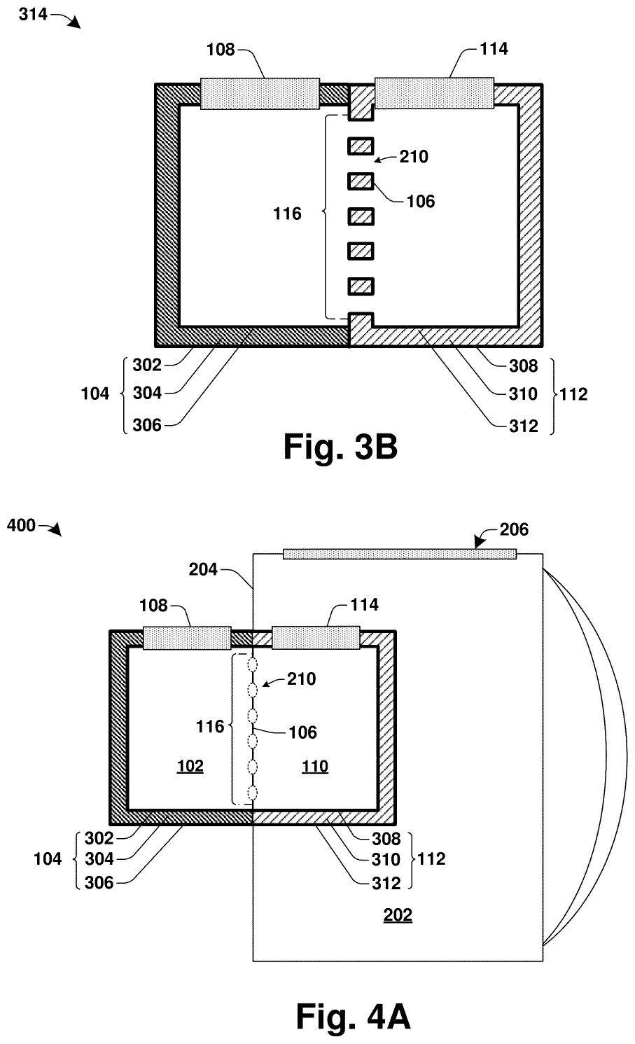

FIGS. 3A-3B illustrate some additional embodiments of disclosed electronic device temperature regulating apparatus having one or more multi-layered membranes.

As shown in FIG. 3A, an electronic device temperature regulating apparatus 300 comprises a first compartment 102 and a second compartment 110 neighboring the first compartment 102. The first compartment 102 may be configured to receive an electronic device (e.g., a cellular phone, a tablet computer, etc.) by way of a first opening 108. The second compartment 110 may be configured to receive a temperature regulation element (e.g., a cooling element) by way of a second opening 114.

The first compartment 102 is arranged between a first membrane 104 and an intervening membrane 106 opposing the first membrane 104. In some embodiments, the first membrane 104 includes a first insulation 304 arranged between a first material layer 302 and a second material layer 306. In some embodiments, the first material layer 302 and/or the second material layer 306 respectively comprise waterproof materials. In some embodiments, the first insulation 304 has a first R-value. In some embodiments, the first material layer 302 and the second material layer 306 form a pouch that completely encloses the first insulation 304 and that is not operable to be selectively opened and closed without damaging the first material layer 302 or the second material layer 306.

The second compartment 110 is arranged between the intervening membrane 106 and a second membrane 112 opposing the intervening membrane 106. In some embodiments, the second membrane 112 includes a second insulation 310 arranged between a third material layer 308 and a fourth material layer 312. In some embodiments, the third material layer 308 and/or the fourth material layer 312 may respectively comprise waterproof materials. In some embodiments, the second insulation 310 has a second R-value. In some embodiments, the third material layer 308 and the fourth material layer 312 form a pouch that completely encloses the second insulation 310 and that is not operable to be selectively opened and closed without damaging the third material layer 308 or the fourth material layer 312.

The intervening membrane 106 includes a thermal transmission region 116 arranged directly between the first compartment 102 and the second compartment 110. In some embodiments, the intervening membrane has a third R-value within the thermal transmission region 116. The third R-value is less than the first R-value and the second R-value.

Including the first insulation 304 within the first membrane 104 and the second insulation 310 within the second membrane 112 allows for a temperature regulation element to keep the first compartment 102 within a desired temperature range (e.g., between approximately 32° F. and approximately 95° F.) for a longer period of time than that achievable by membranes not having insulation. In some embodiment, the first insulation 304 and the second insulation 310 may respectively give the first membrane 104 and the second membrane 112 an R-value that is greater than 2 ft²·° F.·h/BTU, greater than 3 ft²·° F.·h/BTU, greater than 4 ft²·° F.·h/BTU, or other similar values.

As shown in FIG. 3B, in some alternative embodiments, an electronic device temperature regulating apparatus 314 may comprise an intervening membrane 106 having an insulator disposed between material layers (e.g., between material layers including one or more waterproof material layers). In such embodiments, a plurality of perforations 210 within the intervening membrane 106 allow for the transfer of heat, so as to increase a thermal transfer coefficient within a thermal transmission region 116. In some embodiments, the intervening membrane 106 comprises the second insulation 310, the third material layer 308, and the fourth material layer 312 of the second membrane 112. In some such embodiments, the second insulation 310 continuously extends from within the second membrane 112 to within the intervening membrane 106.

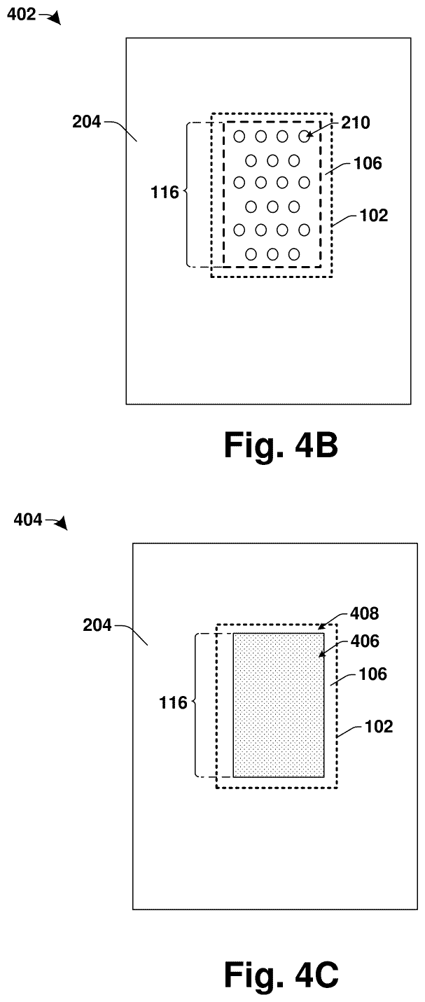

FIG. 4A illustrates some additional embodiments of a disclosed electronic device temperature regulating apparatus 400.

The electronic device temperature regulating apparatus 400 comprises a bag having a flexible housing 204 that selectively encloses an interior cavity 202. A first membrane 104 is coupled to the flexible housing 204 of the bag to form a first compartment 102 arranged along a first side of the flexible housing 204 of the bag. A second membrane 112 is coupled to an interior surface of the bag to form a second compartment 110 along a second side of the flexible housing 204 and within the interior cavity 202.

In some embodiments, the bag may comprise a first material having a first insulative value and the intervening membrane 106 may comprise a second material having a second insulative value. The first membrane 104 includes a first insulation 304 arranged between a first material layer 302 and a second material layer 306. In some embodiments, the first insulation 304 has a third insulative value that is greater than the first and second insulative values. The second membrane 112 includes a second insulation 310 arranged between a third material layer 308 and a fourth material layer 312. In some embodiments, the second insulation 310 has a fourth insulative value that is greater than the first and second insulative values. By having insulation within the first membrane 104 and the second membrane 112, but not within the flexible housing 204, the electronic device temperature regulating apparatus 400 can be formed at a reasonable cost.

FIG. 4B illustrates a plan-view 402 of some embodiments of a flexible housing 204 of a bag that comprises a thermal transmission region 116 arranged within an intervening membrane 106 that separates a first compartment 102 from a second compartment (not shown). The intervening membrane 106 comprises one or more surfaces that form a plurality of perforations 210 extending through the intervening membrane 106 within the thermal transmission region 116.

FIG. 4C illustrates a plan-view 404 of some alternative embodiments of a flexible housing 204 of a bag that comprises a thermal transmission region 116 arranged within an intervening membrane 106 that separates a first compartment 102 from a second compartment (not shown). The intervening membrane 106 comprises a material 406 and a material 408 surrounding material 406. In some embodiments, material 408 may extend beyond outer edges of the first compartment 102. In some embodiments, material 406 may have a larger thermal transmission coefficient than material 408, so that material 406 acts as the thermal transmission region 116 and allows for thermal energy to be transferred between the first compartment 102 and the second compartment (not shown).

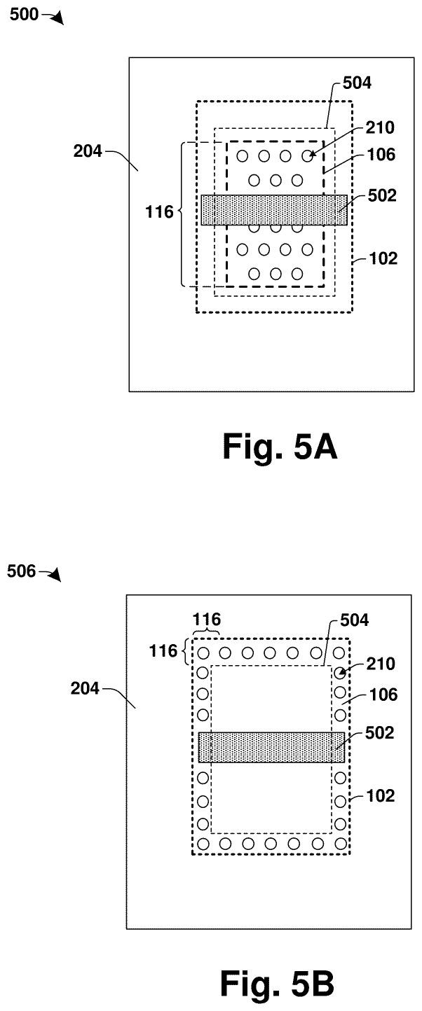

FIG. 5A illustrates a plan-view of some alternative embodiments of a disclosed electronic device temperature regulating apparatus 500.

The electronic device temperature regulating apparatus 500 comprises a bag having a flexible housing 204. The flexible housing 204 includes a thermal transmission region 116 arranged between a first compartment 102 and a second compartment (not shown). In some embodiments, the thermal transmission region 116 may comprise a plurality of perforations 210 extending through the flexible housing 204.

The first compartment 102 may comprise a device clasp 502 (e.g., an electronic device securing apparatus) configured to secure an electronic device to an electronic device receiving area 504 within the first compartment 102. In various embodiments, the device clasp 502 may comprise and/or be an elastic strap, a Velcro strap, or the like. In some embodiments, the device clasp 502 may be attached to the flexible housing 204. In other embodiments, the device clasp 502 may be attached to a first membrane forming the first compartment 102.

In some embodiments, the thermal transmission region 116 may overlap a part or all of the electronic device receiving area 504 so as to improve thermal transmission between a temperature regulation device within the second compartment and the electronic device.

FIG. 5B illustrates a plan-view of some alternative embodiments of a disclosed electronic device temperature regulating apparatus 506.

As shown in FIG. 5B, the thermal transmission region 116 is outside of the electronic device receiving area 504. Having the thermal transmission region 116 outside of the electronic device receiving area 504 may reduce exposure of an electronic device to moisture that may be generated due to a temperature regulation device within a second compartment, while still providing good thermal transmission between the first compartment 102 and the second compartment.

In some embodiments, the thermal transmission region 116 may surround the electronic device receiving area 504. In some such embodiments, the thermal transmission region 116 may be arranged along a peripheral region of the first compartment 102, while the electronic device receiving area 504 may be in a central region of the first compartment 102. In some embodiments, the thermal transmission region 116 may comprise a ring-shaped region that surrounds the electronic device receiving area 504. Having the thermal transmission region 116 surround the electronic device receiving area may reduce exposure of the electronic device to moisture that may be generated due to the temperature regulation device within the second compartment.

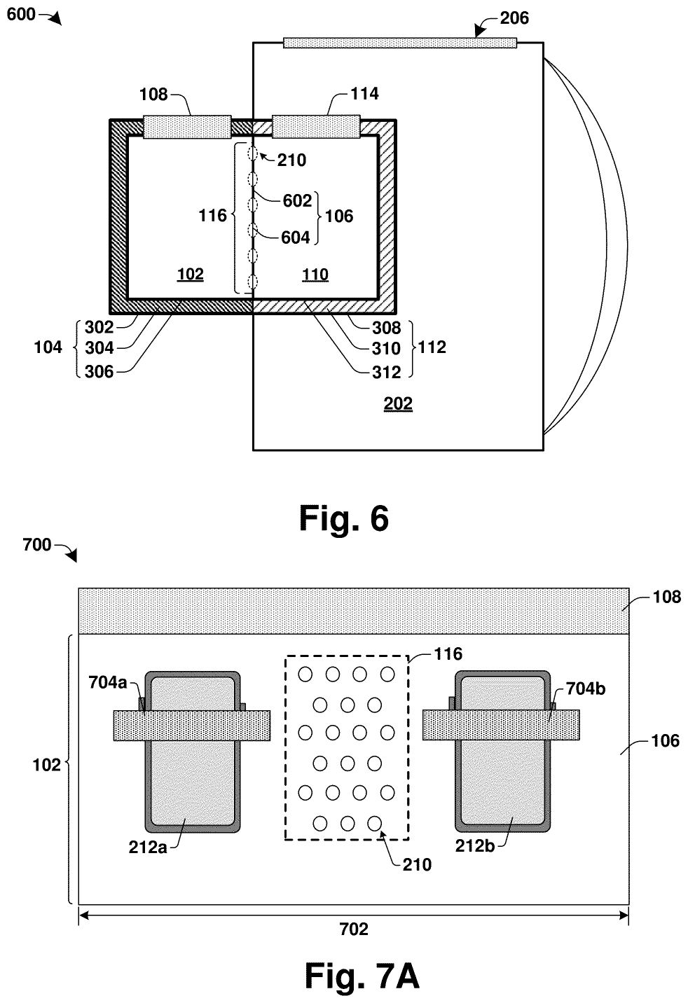

FIG. 6 illustrates some additional embodiments of a disclosed electronic device temperature regulating apparatus 600.

The electronic device temperature regulating apparatus 600 comprises an intervening membrane 106 separating a first compartment 102 and a second compartment 110. The intervening membrane 106 includes a material 602. A plurality of perforations 210 extend through material 602 within a thermal transmission region 116. The intervening membrane 106 further includes a material 604 arranged within the plurality of perforations 210. Material 604 has a smaller insulative value than material 602, so as to allow for heat to be transferred through the plurality of perforations 210 more efficiently than through the material 604. In some embodiments, material 602 and material 604 may comprise waterproof materials. In such embodiments, material 604 allows for heat to be transferred through the plurality of perforations 210 but does not allow for moisture to be transferred through the plurality of perforations 210. Since moisture can damage an electronic device, preventing the transfer of moisture through the thermal transmission region 116 can mitigate damage to an electronic device.

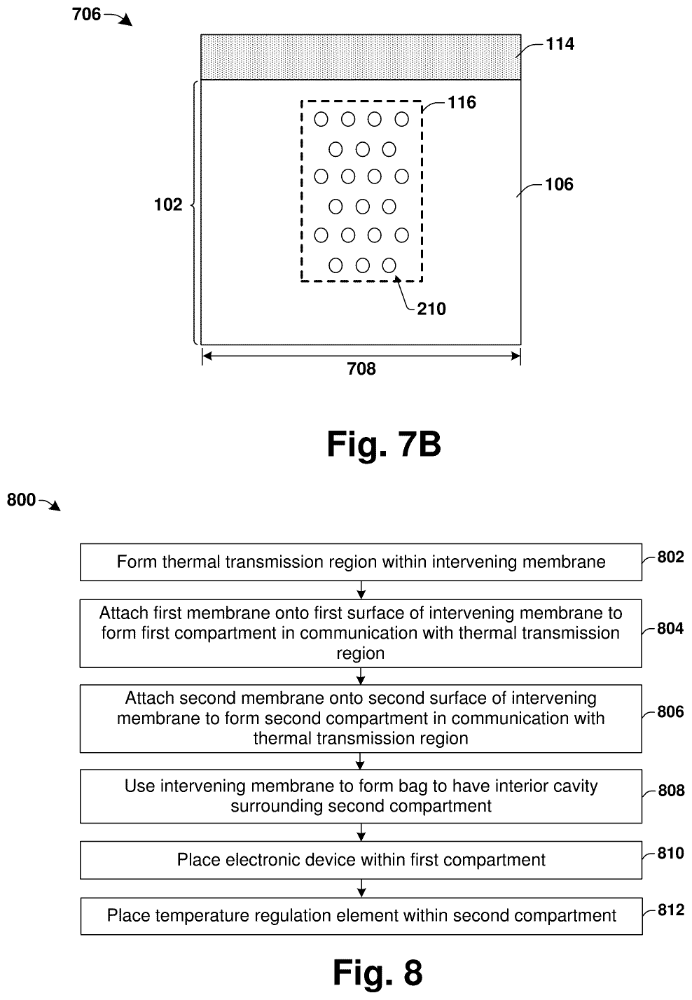

FIGS. 7A-7B illustrate plan-views of some embodiments of first and second compartments of a disclosed electronic device temperature regulating apparatus.

FIG. 7A illustrates a plan-view of some embodiments of a first compartment 700 of a disclosed electronic device temperature regulating apparatus.

The first compartment 700 comprises a thermal transmission region 116 disposed within an intervening membrane 106 arranged between the first compartment 700 and a second compartment (not shown). The thermal transmission region 116 may comprise a plurality of perforations 210 extending through the intervening membrane 106. The first compartment has a first size 702 (e.g., width, length, volume, and/or the like).

In some embodiments, the first compartment 700 comprises a first device clasp 704a and a second device clasp 704b. The first device clasp 704a and a second device clasp 704b are respectively configured to securely hold an electronic device 212 in a substantially fixed position. In some embodiments, the first device clasp 704a and the second device clasp 704b are disposed along opposing sides of the thermal transmission region 116. In some embodiments, the first device clasp 704a and the second device clasp 704b may comprise hook and loop straps or the like.

FIG. 7B illustrates a plan-view of some embodiments of a second compartment 706 of a disclosed electronic device temperature regulating apparatus.

The second compartment 706 comprises a thermal transmission region 116 disposed within an intervening membrane 106. The thermal transmission region 116 may comprise a plurality of perforations 210 extending through the intervening membrane 106. The second compartment 706 has a second size 708 (e.g., width, length, volume, and/or the like). In some embodiments, the second size 708 is smaller than the first size (e.g., 702 of FIG. 7A). For example, the first compartment (e.g., 700 of FIG. 7) may extend to non-zero distances past opposing sides of the second compartment 706.

FIG. 8 illustrates a flow diagram of some embodiments of a method of forming a disclosed electronic device temperature regulating apparatus.

While method 800 is illustrated and described herein as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At act 802, a thermal transmission region is formed within an intervening membrane. The thermal transmission region has a higher thermal transfer coefficient than a region of the intervening membrane outside of the thermal transmission region. In some embodiments, the thermal transmission region may be formed by forming a plurality of perforations within a part of the intervening membrane.

At act 804, a first membrane is attached to a first surface of the intervening membrane to form a first compartment in communication with the thermal transmission region. In some embodiments, the first membrane may cover the thermal transmission region.

At act 806, a second membrane is attached to a second surface of the intervening membrane to form a second compartment in communication with thermal transmission region. The second surface opposes the first surface. In some embodiments, the second membrane may cover the thermal transmission region.

At act 808, the intervening membrane is used to from a bag having an interior cavity surrounding the second compartment.

At act 810, an electronic device is placed within the first compartment.

At act 812, a temperature regulation element is placed within the second compartment.

Therefore, the present disclosure relates to an electronic device temperature regulating apparatus that is configured to maintain a temperature of an electronic device (e.g., a smartphone) within an operating range that is above or below a temperature of a surrounding ambient environment.

In some embodiments, the present disclosure relates to an electronic device temperature regulating apparatus that includes a first compartment arranged between a first membrane including a first material having a first insulative value and an intervening membrane opposing the first membrane; a second compartment arranged between the intervening membrane and a second membrane including a second material having a second insulative value; and the intervening membrane including a thermal transmission region that is directly between the first compartment and the second compartment, the thermal transmission region having a third insulative value that is less than the first insulative value and the second insulative value.

In other embodiments, the present disclosure relates to an electronic device temperature regulating apparatus that includes a flexible housing selectively enclosing an interior cavity, the flexible housing having a first opening that can be selectively closed and opened to provide access to the interior cavity; a first membrane attached to an exterior surface of the flexible housing to form a first compartment arranged along the exterior surface of the flexible housing, the first compartment having opening that is in communication with the first compartment; a second membrane attached to an interior surface of the flexible housing to form a second compartment within the interior cavity, the second compartment being separated from the first compartment by a thermal transmission region arranged therebetween; and the thermal transmission region providing for thermal communication between the first compartment and the second compartment.

In yet other embodiments, the present disclosure relates to a method of forming an electronic device temperature regulating apparatus that includes forming a thermal transmission region within an intervening membrane, the thermal transmission region having a higher thermal transfer coefficient than a region of the intervening membrane outside of the thermal transmission region; attaching a first membrane onto a first surface of the intervening membrane to form a first compartment; attaching a second membrane onto a second surface of intervening membrane to form a second compartment that is in communication with the first compartment by way of the thermal transmission region, the second surface opposing the first surface; and using the intervening membrane to form a bag having an interior cavity configured to surround the second compartment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An electronic device temperature regulating apparatus, comprising:
a first compartment arranged between a first membrane including a first material having a first insulative value and an intervening membrane opposing the first membrane;
a second compartment arranged between the intervening membrane and a second membrane including a second material having a second insulative value; and
wherein the intervening membrane includes a thermal transmission region that is directly between the first compartment and the second compartment, the thermal transmission region having a third insulative value that is less than the first insulative value and the second insulative value.

2. The electronic device temperature regulating apparatus of claim 1, wherein the first insulative value is a first R-value, the second insulative value is a second R-value, and the third insulative value is a third R-value that is less than the first R-value and the second R-value.

3. The electronic device temperature regulating apparatus of claim 1,
wherein the intervening membrane comprises a third material having a fourth insulative value larger than the third insulative value; and
wherein the thermal transmission region comprises a plurality of perforations extending through the third material and a fourth material arranged within the perforations, the fourth material having a smaller insulative value than the third material.

4. The electronic device temperature regulating apparatus of claim 1, wherein the intervening membrane comprises a third material having the third insulative value and a fourth material surrounding the third material.

5. The electronic device temperature regulating apparatus of claim 1, wherein the thermal transmission region comprises a moisture wicking fabric.

6. The electronic device temperature regulating apparatus of claim 1, wherein the thermal transmission region comprises a waterproof material.

7. The electronic device temperature regulating apparatus of claim 1, wherein the first membrane and the second membrane respectively comprise an insulator disposed between material layers comprising one or more waterproof material layers.

8. The electronic device temperature regulating apparatus of claim 1, wherein the first compartment comprises a first device clasp and a second device clasp disposed along opposing sides of the thermal transmission region.

9. The electronic device temperature regulating apparatus of claim 8, wherein the first device clasp and the second device clasp comprise hook and loop straps.

10. An electronic device temperature regulating apparatus, comprising:
a flexible housing selectively enclosing an interior cavity, the flexible housing having a first opening that can be selectively closed and opened to provide access to the interior cavity;
a first membrane attached to an exterior surface of the flexible housing to form a first compartment arranged along the exterior surface of the flexible housing, the first compartment having opening that is in communication with the first compartment;
a second membrane attached to an interior surface of the flexible housing to form a second compartment within the interior cavity, wherein the second compartment is separated from the first compartment by a thermal transmission region arranged therebetween; and
wherein the thermal transmission region provides for thermal communication between the first compartment and the second compartment.

11. The electronic device temperature regulating apparatus of claim 10, wherein the flexible housing has a first thermal transfer coefficient and the thermal transmission region has a second thermal transfer coefficient that is larger than the first thermal transfer coefficient.

12. The electronic device temperature regulating apparatus of claim 10, wherein the interior cavity has a first size, the first compartment has a second size that is smaller than the first size, and the second compartment has a third size that is smaller than the first size.

13. The electronic device temperature regulating apparatus of claim 10, further comprising:
a reusable cooling element disposed within the second compartment, wherein the reusable cooling element is configured to reduce a temperature within the second compartment.

14. The electronic device temperature regulating apparatus of claim 13, wherein the reusable cooling element is configured to cool the first compartment to a lower temperature than the interior cavity.

15. The electronic device temperature regulating apparatus of claim 10, wherein the exterior surface of the flexible housing is white.

16. The electronic device temperature regulating apparatus of claim 10, wherein the first membrane has a first insulator disposed between first waterproof material layers and the second membrane has a second insulator disposed between second waterproof material layers.

17. The electronic device temperature regulating apparatus of claim 10, wherein the first compartment comprises a device clasp configured to secure an electronic device to an electronic device receiving area within the first compartment.

18. The electronic device temperature regulating apparatus of claim 10, wherein the first compartment has a size that is substantially equal to the second compartment.

19. The electronic device temperature regulating apparatus of claim 10, wherein the first compartment has a size that is less than the second compartment.

20. A method of forming an electronic device temperature regulating apparatus, comprising:
forming a thermal transmission region within an intervening membrane, the thermal transmission region having a higher thermal transfer coefficient than a region of the intervening membrane outside of the thermal transmission region;
attaching a first membrane onto a first surface of the intervening membrane to form a first compartment;
attaching a second membrane onto a second surface of intervening membrane to form a second compartment that is in communication with the first compartment by way of the thermal transmission region, wherein the second surface opposes the first surface; and
using the intervening membrane to form a bag having an interior cavity configured to surround the second compartment.
